(19) United States
(12) Patent Application Publication
(10) Pub. No.: US 2007/0087274 A1
(43) Pub. Date: Apr. 19, 2007

(54) Wiring correction method

(75) Inventors: Ruriko Kukita, Kanagawa (JP); Yoshimi Takahashi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: LASERFRONT TECHNOLOGIES, INC.

(21) Appl. No.: 11/580,070

(22) Filed: Oct. 13, 2006

(30) Foreign Application Priority Data
Oct. 14, 2005 (JP) 2005-300944

(51) Int. Cl. G03F 1/00

(52) U.S. Cl. 430/5

(57) ABSTRACT

The presence of defects in a wiring pattern is checked by a visual method, by image processing, or the like, and when a defect is detected, information such as the position, coordinates, and size of the defect is confirmed, the type of defect is confirmed, and a processing method and processing conditions are set in accordance with the defect type and conditions (step S1). Shorting defects are corrected based on the processing method and processing conditions that have been set and the defect information that has been confirmed (step S2). Subsequently, disconnection defects are corrected based on the set processing method and processing conditions and the confirmed defect information (step S3). Upon completion of these correction operations, a determination is made as to whether the defects have been corrected (step S4). By this means, the operating time for wiring correction can be shortened, and automation facilitated.

### BACKGROUND OF THE INVENTION

1. Field of the Invention

The present invention relates to a wiring correction method for correcting defective portions of wiring formed on a substrate, and more specifically relates to a wiring correction method that is performed after forming a wiring pattern in steps for manufacturing a liquid crystal device and a semiconductor device.

2. Description of the Related Art

In the prior art, steps for manufacturing a TFT (thin film transistor) substrate used in a liquid crystal display device include repeating a step for forming a wiring pattern on a glass substrate, a step for inspecting the pattern, and a step for correcting the pattern (e.g., refer to Japanese Laid-Open Patent Application No. 10-177,844). FIG. 1 is a diagram showing a conventional TFT substrate fabrication step. As shown in FIG. 1, manufacturing of TFT substrates in the prior art involves performing a glass substrate introduction step (step S101), followed by a film formation step (step S102), a resist application step (step S103), an exposure step (step S104), a development step (step S105), and an etching step (step S106) to form a wiring pattern on the glass substrate.

After the etching step, the wiring pattern formed in steps S102 to S106 is inspected for electrical circuit functionality using an array tester, and the presence of disconnection defects or shorting defects is determined using an open/short tester while the pattern is also inspected for pattern shape defects using a visual tester (step S107). When, defects are discovered (NG) as a result of these inspections, the defects that have been discovered by the inspections are corrected (step S108). Subsequent to defect correction, lack of defects in the substrate is confirmed, and a film is again formed on the substrate in order to form the subsequent wiring pattern. On the other hand, substrates that are determined to have no defects (OK) in the inspection step occurring subsequent to the etching step are sent to the film formation step without being subjected to the correction step. By repeating these steps, a TFT array is generated on the glass substrate. The manufacturing, inspection, and correction steps are generally integrated and controlled by means of CIM (computer integrated manufacturing) or the like.

In addition, repair (correction) devices have been offered in the prior art that automatically and sequentially carry out the various post-etching defect inspections, corrections, and post-correction inspections (e.g., Japanese Laid-Open Patent Application Nos. 06-27479 and 2004-297452).

However, the following problems have occurred with the conventional techniques described above. FIG. 2 is a flowchart that shows the inspection and correction steps in the conventional TFT substrate manufacturing step shown in FIG. 1. As shown in FIG. 2, when defects are inspected and corrected in a wiring pattern formed on a TFT substrate, first, the presence of defects is confirmed visually by image processing or the like in the inspection part of step S107. When defects are detected, the positions, coordinates, sizes, and the like are recorded (this confirmation operation is referred to below as “review”). Next, shorting defects, disconnection defects, and other defects in the wiring pattern are corrected based on the defect detection information obtained in the inspection step. At this time, after reviewing the shorting defects in the shorting defect correction step, the operator selects the processing method and processing conditions in accordance with the defect condition, and, for example, the portions that are shorted are removed using a laser or the like (step S108a). Similarly, in the disconnection defect correction step, after reviewing the disconnection defects, the operator selects the processing method and processing conditions in accordance with the defect condition, and the disconnected portions of the wiring are interpolated and connected by, for example, laser CVD (chemical vapor deposition) or the like (step S108b). Upon completion of these correction steps, a determination is made (step S108c), and if the results indicate that the defects have been corrected, then the substrate is sent to the subsequent step, such as a film formation step or the like. If the defects have not been corrected, then the substrate is returned for inspection, and a correction step is performed.

In conventional TFT substrate manufacturing steps, reviewing and other substantially shared operations are thus duplicated in the inspection, shorting defect correction, and disconnection defect correction steps. The processing time is therefore long, and there are problems with increased labor. The wiring pattern inspection and correction steps described above are also carried out in the semiconductor device manufacturing step, and thus the same problems arise in this step.

### SUMMARY OF THE INVENTION

An object of the present invention is to provide a wiring correction method whereby the operating time can be shortened and automation facilitated.

The wiring correction method according to a first aspect of the present invention for correcting defects in wiring formed on substrates, said method comprises the steps of:

checking for the presence of a defect on each substrate, and, when the defect is detected, recording information about the defect, including the position, type, and size of the defect, and setting a correction method and correction conditions for each of the defect types; and

correcting the defect, on the substrate on which the presence of the defect has been detected in the detection and setting step, in accordance with the defect type, on the basis of the information about the defect recorded in the detection and setting step, and on the basis of the correction method and correction conditions set in the detection and setting step.

In the present invention, the correction method and correction conditions are set in accordance with the type of detected defect in the defect detection step carried out prior to the defect correction step, and thus review is not necessary in the defect correction step. As a result, the operation time can be shortened. In addition, because processing is carried out under preset conditions, the defect correction step can be simplified and automated.

The defect correction step may comprise a shorting defect correction step for removing portions in which the wiring has shorted, and a disconnection defect correction step for interpolating and connecting disconnected portions of the wiring. The method may further comprise a determination step for checking that the defect has been corrected subsequent to the defect correction step, and repeating the detection and setting step and the defect correction step when the defect is determined to have not been corrected in the determination step.

The wiring correction method according to a second aspect of the present invention is a defect correction method for correcting defects in wiring formed on substrates, the method comprising the steps of:

checking for the presence of a first defect on each substrate, and, when the first defect is detected, recording information about the first defect, including the position, type, and size of the first defect;

a first defect correcting by determining the type of the first defect on the substrate on which the presence of the first defect has been detected in the detection step, setting a correction method and correction conditions for this type of the first defect, and correcting the first defect on the basis of the information about the first defect recorded in the detection step and on the basis of the set correction method and correction conditions; and

a second defect correcting by correcting a second defect on the basis of defect information recorded in the detection step for the second defect and on the basis of the correction method and correction conditions set in the first defect correction step.

In the present invention, review is unnecessary in the second defect correction step because the subsequently performed correction method and correction conditions for correcting the second defect are set in the previously performed first defect correction step. As a result, the operation time can be shortened and the second defect correction step can be simplified and automated.

The first defect is a shorting defect, and the first defect correction step is a shorting defect correction step involving removal of the portion where the wiring has shorted. The second defect is a disconnection defect, and the second defect correction step may be a disconnection defect correction step in which disconnected portions of the wiring are interpolated and connected. The method may further comprise a determination step for checking that defects have been corrected subsequent to the second defect correction step, and repeating the detection step and the first and second defect correction steps when the defects are detected to have not been corrected.

In the present invention, the correction methods and correction conditions are set for each type of detected defect in the defect detection step or the previously performed correction step. Therefore, review is not necessary in the subsequently performed defect correction step. As a result, the operation time can be shortened and the subsequently performed defect correction step can be easily automated.

### BRIEF DESCRIPTION OF THE DRAWINGS

FIG. 1 is a flowchart showing a conventional TFT substrate manufacturing step;

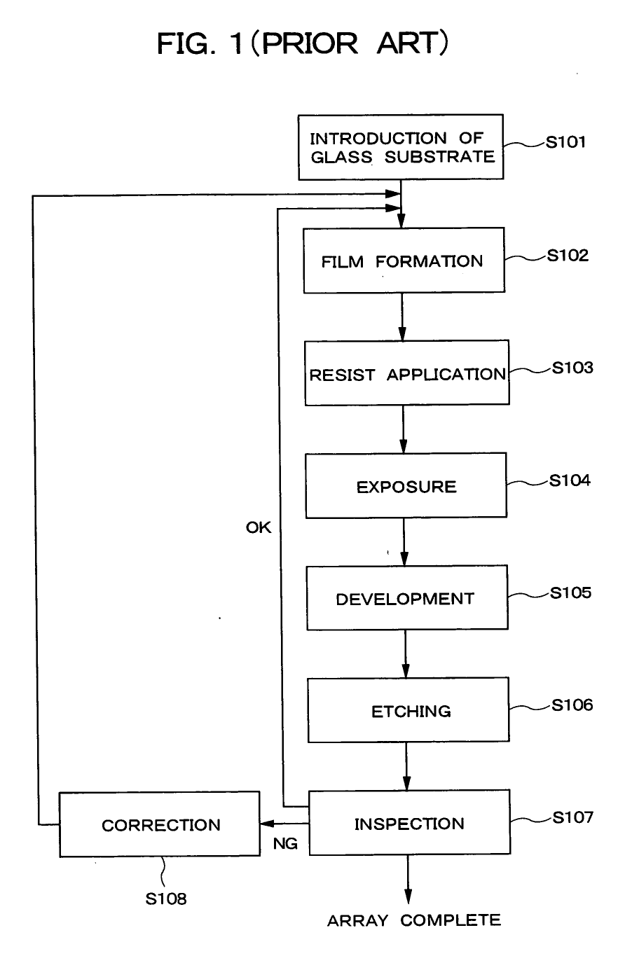

FIG. 2 is a flowchart showing the inspection step and correction step in the TFT substrate manufacturing step shown in FIG. 1;

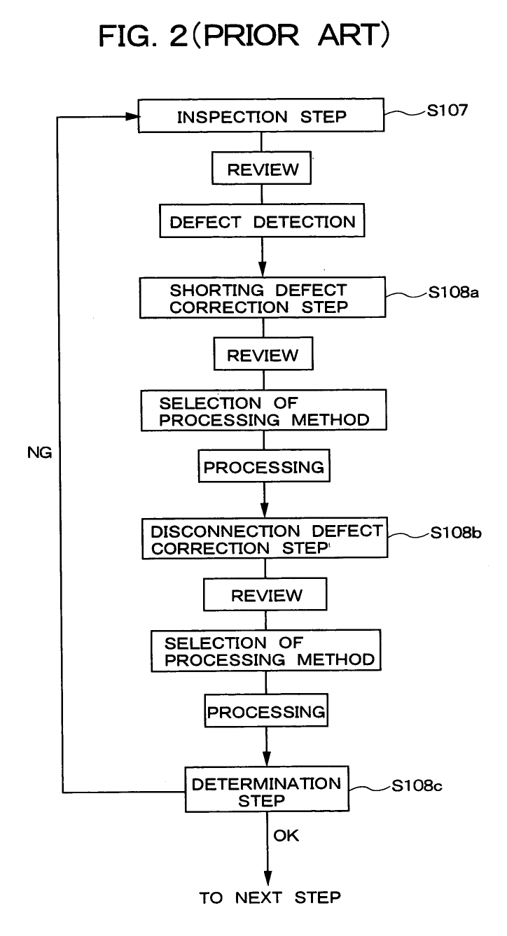

FIG. 3 is a flowchart showing the wiring correction method for a first embodiment of the present invention; and

FIG. 4 is a flowchart showing the wiring correction method for a second embodiment of the present invention.

### DESCRIPTION OF THE PREFERRED EMBODIMENTS

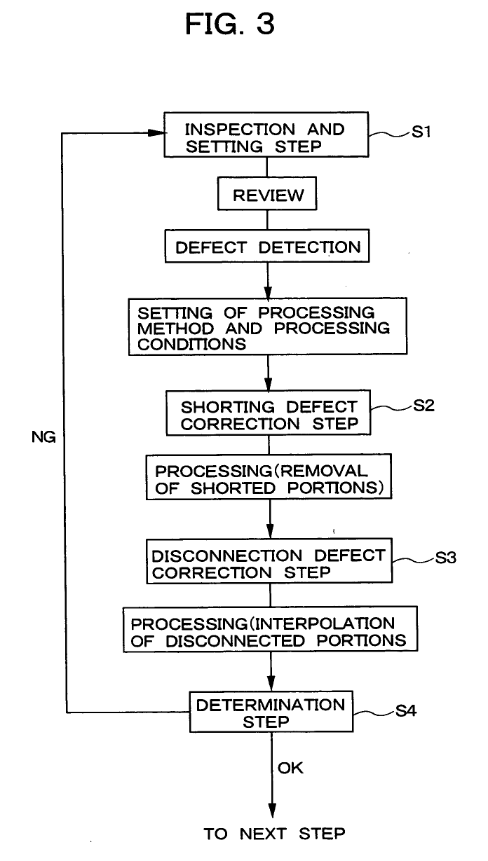

The wiring correction method according to an embodiment of the present invention is described in detail below in reference to the attached figures. The wiring correction method of the first embodiment of the present invention will be described first. FIG. 3 is a flowchart showing the wiring correction method of this embodiment. The wiring correction method of this embodiment is a method for detecting and correcting defects such as shorting defects and disconnection defects. The method is carried out after a wiring pattern has been formed in a step for manufacturing a TFT substrate for a liquid crystal display device, a step for forming the wiring of a semiconductor device, or the like. As shown in FIG. 3, the wiring correction method of this embodiment involves first detecting a wiring pattern defect, recording information regarding the defect, and then establishing the necessary settings for the subsequent correction step (step S1). Specifically, for each substrate, the presence of defects in the wiring pattern is checked by a visual method, by image processing, or the like. Then, when a defect has been detected, information such as the position, coordinates, and size of the defect is checked and recorded. In addition, the type of defect, i.e., a shorting defect or a disconnection defect, is determined, and the process method and process conditions are set in accordance with the defect type and conditions. Defect checking and determination can also be carried out alone without processing. Defects that are deemed acceptable based on the results of the review remain unprocessed. Only a determination alone can be made for some defects. These aspects depend on user specifications.

Next, the shorting defect correction step (step S2) and the disconnection defect correction step (step S3) are carried out based on the information recorded in the detection and setting part of step S1. At this time, the portion where a shorting defect has occurred is removed in a shorting defect detection/correction step in accordance with the processing method and processing conditions set in the detection and setting step. Portions having disconnected wiring are also interpolated and connected in the disconnection defect correction step in accordance with the processing method and processing conditions set in the detection and setting step.

Upon completion of the correction steps, a determination is made as to whether the defects have been corrected (step S4). As a result, in cases where the defects have been corrected, and a determination of “no defect (OK)” has been made, the substrate is sent to the subsequent step, such as a film formation step. If the defects have not been corrected, and a determination that defects are present (NG) has been made, then steps S1 to S3 are repeated.

In the wiring correction method of this embodiment, the detected defect type, processing method, and processing conditions are set in the defect detection step carried out prior to the defect correction step, making it unnecessary to perform review in the shorting defect correction step and the disconnection defect correction step. It is thereby possible to shorten the operation time and to eliminate operator standby, allowing an improvement in operational efficiency. Moreover, in the wiring correction method of this embodiment, each of the correction steps involves only processing under preset conditions. Therefore, automation can be facilitated and labor requirements reduced.

In the wiring correction method of this embodiment, common inspection devices and correction devices can be used, and the devices should preferably share a coordinate system and perform adjustments using offsets, shared markings, or the like. In addition, the inspection devices and correction devices that are used should preferably be linked together by some communication means. In addition, the wiring correction method of this embodiment was described with reference to a case in which disconnection defects are corrected after shorting defects have been corrected, but the present invention is not limited to this option along, and shorting defects may be corrected after disconnection defects have been corrected.

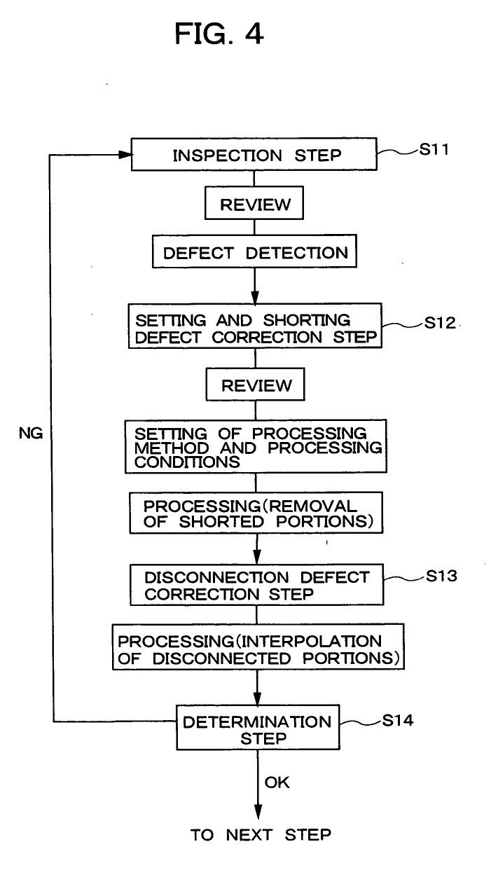

The wiring correction method of a second embodiment of the present invention is described below. In the wiring correction method of the first embodiment, settings for corrections were made at the time of defect detection, but the present invention is not limited to this option alone. An inspection step may be carried out that involves only checking for the presence of defects as in the prior art, whereupon setting of the processing method and processing conditions required for the subsequent correction step may be carried out in the previously performed defect correction step. FIG. 4 is a flowchart that shows the wiring correction method of the second embodiment of the present invention. As shown in FIG. 4, in the wiring correction method of this embodiment, an inspection step is first carried out by the same method as in the prior art (step S11). Specifically, the presence of defects in the wiring pattern formed on the substrate is checked, and, when the defect is present, the position, coordinates, size, and the like are recorded.

With substrates for which a determination of “defects present” is made in the inspection step, settings for correcting the defect are subsequently established, and shorting defects are corrected (step S12). Specifically, the defects confirmed in the inspection step are reviewed, and the method and conditions for processing the defects are set by an operator in accordance with the defect types and conditions. Next, the methods and conditions thus set are used in order to remove the shorted portions, thereby correcting the shorting defects. The disconnected portions of the wiring are then interpolated and connected in accordance with the method and conditions set in the setting and shorting defect correction step, and the disconnection defects are corrected (step S13).

Upon completion of all correction steps, a determination as to whether the defects have been corrected is made (step S14). If the results indicate that the defects have been corrected and the determination “no defect (OK)” is made, then the substrate is sent to a subsequent step such as a film formation step. If the defects have not been corrected and a determination of “defects present (NG)” is made, then steps S11 to S13 are carried out again.

In the wiring correction method of this embodiment, the processing method and processing conditions required for the subsequently performed disconnection defect correction step are set in the previously performed shorting defect correction step, and review is therefore not necessary in the disconnection defect correction step. The operation time can thereby be shortened and operator standby time eliminated, allowing for an increase in operational efficiency. In addition, the subsequently performed disconnection defect correction step is carried out under preset conditions. Therefore, automation can be facilitated and labor requirements reduced.

In the wiring correction method of this embodiment, disconnection defects are corrected after shorting defects have been corrected, but the present invention is not limited to this option alone, and shorting defects can be corrected after disconnection defects have been corrected. In this case, the processing method and processing conditions for correcting the shorting defects are established in the disconnection defect correction step.

In the wiring correction method of the first and second embodiments described above, shorting defects and disconnection defects alone were corrected, but the present invention is not limited to this option alone. Correction steps for defects other than shorting defects and disconnection defects may also be carried out, and three or more defect correction steps may be performed.

What is claimed is:

1. A defect correction method for correcting defects in wiring formed on substrates, said method comprising the steps of:
checking for the presence of a defect on each substrate, and, when the defect is detected, recording information about the defect, including the position, type, and size of the defect, and setting a correction method and correction conditions for each of the defect types; and
correcting the defect, on the substrate on which the presence of the defect has been detected in the detection and setting step, in accordance with the defect type, on the basis of the information about the defect recorded in the detection and setting step, and on the basis of the correction method and correction conditions set in the detection and setting step.

2. The method of claim 1, wherein the defect correction step further comprises the steps of:
correcting a shorting defect by removing portions in which the wiring has shorted; and
correcting a disconnection defect by interpolating and connecting disconnected portions of the wiring.

3. The method of claim 1, further comprising the steps of:
determining and checking that the defect has been corrected subsequent to the defect correction step, and repeating the detection and setting step and the defect correction step when the defect is determined to have not been corrected in the determination step.

4. The method of claim 2, further comprising the steps of:
determining and checking that the defect has been corrected subsequent to the defect correction step, and repeating the detection and setting step and the defect correction step when the defect is determined to have not been corrected in the determination step.

5. A defect correction method for correcting defects in wiring formed on substrates, said method comprising the steps of:
checking for the presence of a first defect on each substrate, and, when the first defect is detected, recording information about the first defect, including the position, type, and size of the first defect;
a first defect correcting by determining the type of the first defect on the substrate on which the presence of the first defect has been detected in the detection step, setting a correction method and correction conditions for this type of the first defect, and correcting the first defect on the basis of the information about the first defect recorded in the detection step and on the basis of the set correction method and correction conditions; and
a second defect correcting by correcting a second defect on the basis of defect information recorded in the detection step for the second defect and on the basis of the correction method and correction conditions set in the first defect correction step.

6. The defect correction method according to claim 5, wherein
the first defect is a shorting defect, and the first defect correction step is a shorting defect correction step in which the portions in which the wiring has shorted are removed; and
the second defect is a disconnection defect, and the second defect correction step is a disconnection defect correction step in which disconnected portions of the wiring are interpolated and connected.

7. The defect correction method according to claim 5, further comprising the steps of determining and checking that defects have been corrected subsequent to the second defect correction step, and repeating the detection step and the first and second defect correction steps when the defects are determined to have not been corrected in the determination step.

8. The defect correction method according to claim 6, further comprising the steps of determining and checking that defects have been corrected subsequent to the second defect correction step, and repeating the detection step and the first and second defect correction steps when the defects are determined to have not been corrected in the determination step.
